(19) United States
(12) Patent Application Publication
(10) Pub. No.: US 2026/0005667 A1
(43) Pub. Date: Jan. 1, 2026

(54) RESONATOR ELEMENT

(71) Applicant: SEIKO EPSON CORPORATION, Tokyo (JP)

(72) Inventor: Kazuyuki Nagata, Minowa-machi (JP)

(21) Appl. No.: 19/251,397

(22) Filed: Jun. 26, 2025

(30) Foreign Application Priority Data
Jun. 28, 2024 (JP) 2024-104913

(51) Int. Cl. H03H 9/02

(52) U.S. Cl. CPC H03H 9/02448; H03H 9/02259; H03H 2009/02251; H03H 2009/02291

(57) ABSTRACT

A resonator element includes three vibrating arms. Each of the three vibrating arms includes an arm extending from a base and a wide section positioned at a tip end portion of the arm. The wide section is wider than the arm. When, of the three vibrating arms, the vibrating arm positioned at a center of an arrangement is provided with the arm having a width denoted by W1 which is defined as a length of the arm in the second direction, and the vibration arms positioned on both sides of the arrangement are provided with the arms each having a width denoted by W2 which is defined as a length of the arms in the second direction, a relationship 1≤W1/W2≤2 is satisfied. When a length of the three vibrating arms in the first direction is denoted by L and a length of the wide sections in the first direction is denoted by Lh, a relationship Lh/L≤0.49 is satisfied.

The present application is based on, and claims priority from JP Application Serial Number 2024-104913, filed Jun. 28, 2024, the disclosure of which is hereby incorporated by reference herein in its entirety.

### BACKGROUND

### 1. Technical Field

The present disclosure relates to resonator elements.

### 2. Related Art

JP-A-2012-160996 describes a silicon resonator element that includes a base and three vibrating arms extending from the base in the Y-axis direction. The three vibrating arms are arranged in the X-axis direction orthogonal to the Y-axis direction and have piezoelectric elements on upper surfaces thereof. When the piezoelectric elements to which the drive voltage is applied expand and contract, the vibrating arms vibrate in the Z-axis direction orthogonal to the X-axis and the Y-axis. In a case where, of the three vibrating arms, the vibrating arm positioned at the center of the arrangement has a width denoted by W1 and the two vibrating arms positioned on both sides of the arrangement have a width denoted by W, a relationship 1.35<W1/W<1.90 is satisfied to suppress the Q value from deteriorating.

JP-A-2012-160996, however, has no description about a configuration in which wide sections are formed at the tip end portions of the respective vibrating arms. Thus, conditions for suppressing the Q value of a resonator element having wide sections from deteriorating are unclear.

### SUMMARY

The present disclosure is a resonator element that includes a base and three vibrating arms that extend from the base in a first direction and that are arranged side by side in a second direction orthogonal to the first direction. Each of the three vibrating arms includes an arm extending from the base and a wide section positioned at a tip end portion of the arm. The wide section is wider than the arm. When, of the three vibrating arms, the vibrating arm positioned at a center of an arrangement is provided with the arm having a width denoted by W1 which is defined as a length of the arm in the second direction, and the vibration arms positioned on both sides of the arrangement are provided with the arms each having a width denoted by W2 which is defined as a length of the arms in the second direction, a relationship 1≤W1/W2≤2 is satisfied. When a length of the three vibrating arms in the first direction is denoted by L and a length of the wide sections in the first direction is denoted by Lh, a relationship Lh/L≤0.49 is satisfied.

### BRIEF DESCRIPTION OF THE DRAWINGS

FIG. 1 is a plan view of a MEMS device according to a preferred embodiment.

FIG. 2 is a cross-sectional view taken along line II-II in FIG. 1.

FIG. 3 is a plan view of a resonator element disposed in the MEMS device.

FIG. 4 is a cross-sectional view of a vibrating arm disposed in the resonator element.

FIG. 5 is a graph showing the relationship between W1/W2 and the Q value.

FIG. 6 is a graph showing the relationship between Lh/L and the Q value.

### DESCRIPTION OF EMBODIMENTS

Hereinafter, a resonator element according to the present disclosure will be described in detail based on embodiments illustrated in the accompanying drawings.

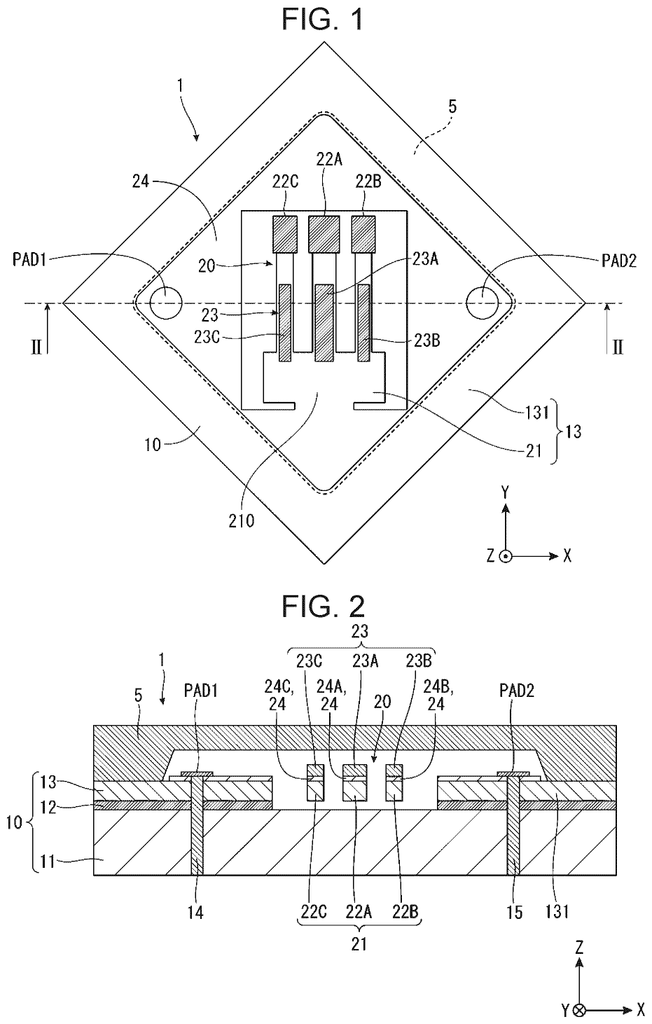

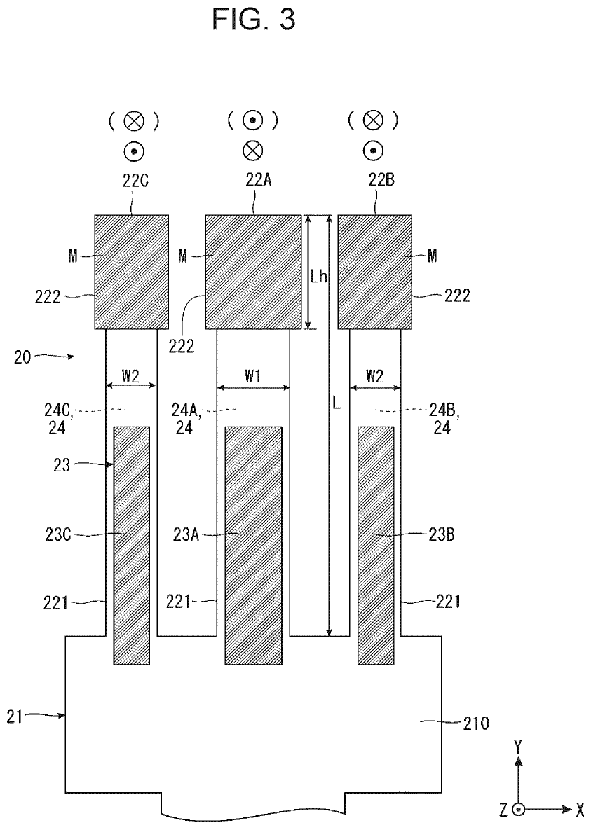

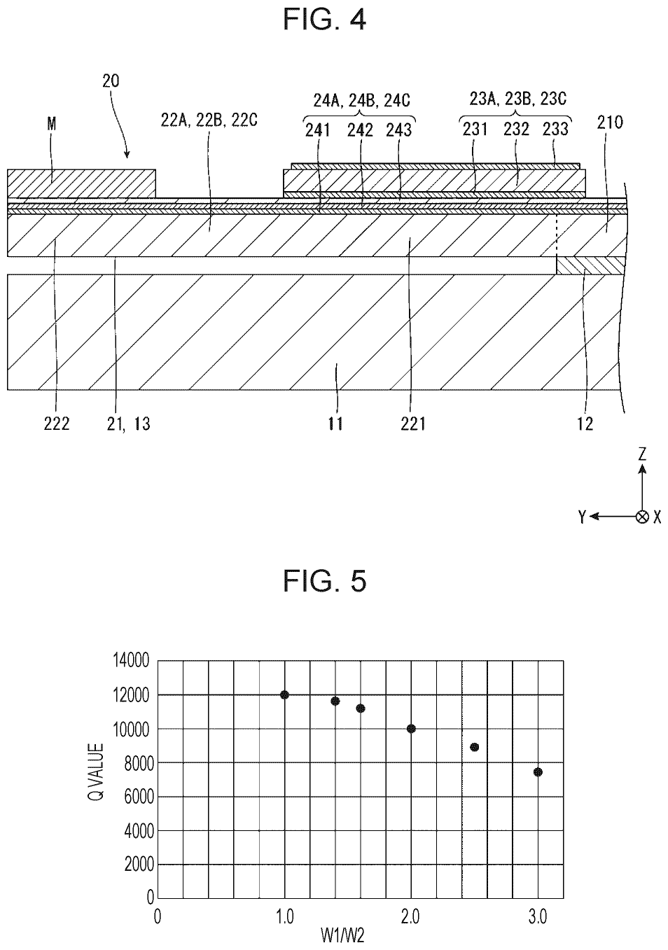

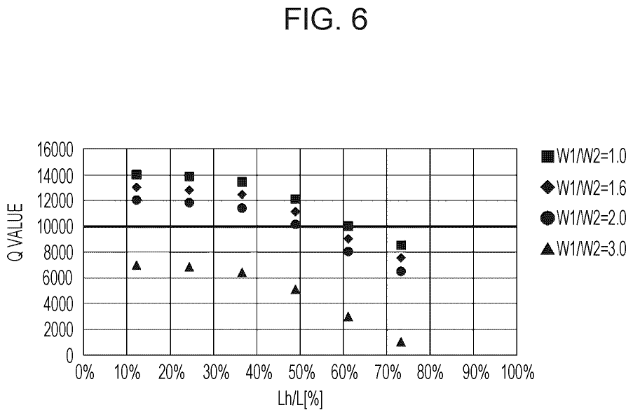

FIG. 1 is a plan view of a MEMS device according to a preferred embodiment. FIG. 2 is a cross-sectional view taken along line II-II in FIG. 1. FIG. 3 is a plan view of a resonator element disposed in the MEMS device. FIG. 4 is a cross-sectional view of a vibrating arm disposed in the resonator element. FIG. 5 is a graph showing the relationship between W1/W2 and the Q value. FIG. 6 is a graph showing the relationship between Lh/L and the Q value.

For convenience of the description, an X-axis, a Y-axis, and a Z-axis orthogonal to each other are illustrated in each of FIGS. 1 to 4. In addition, a direction along the X axis is referred to as an X-axis direction; a direction along the Y axis is referred to as a Y-axis direction; and a direction along the Z axis is referred to as a Z-axis direction. Herein, the X-axis direction corresponds to a “second direction”, whereas the Y-axis direction corresponds to a “first direction”. In addition, an arrow side of each axis is referred to as a positive side, whereas an opposite side is referred to as a negative side. A positive side in the Z-axis direction is referred to as “upward”, whereas a negative side is referred to as “downward”.

As illustrated in FIGS. 1 and 2, a MEMS device 1 includes a silicon-on-insulator (SOI) substrate 10 on which a resonator element 20 is formed and a lid 5 that hermetically encloses the resonator element 20 between the SOI substrate 10 and the lid 5. The lid 5, which is made of single-crystal silicon or some other material, has a depression formed on a lower surface thereof. The lower surface of the lid 5 is bonded to an upper surface of the SOI substrate 10. As illustrated in FIG. 2, the SOI substrate 10 is a multilayer substrate in which a silicon layer 11 formed as a handle layer, a buried oxide (BOX) layer 12, and a surface silicon layer 13 formed as a device layer are stacked in this order from the lower side. For example, each of the silicon layer 11 and the surface silicon layer 13 is made of single crystal silicon, whereas the BOX layer 12 is made of a silicon oxide (SiO₂) layer.

As illustrated in FIG. 1, the surface silicon layer 13 includes a vibrating substrate 21 disposed in the resonator element 20 and a frame 131 surrounding the vibrating substrate 21. A pair of electrode pads PAD1 and PAD2 are disposed on an upper surface of the frame 131. As illustrated in FIG. 2, through-electrodes 14 and 15 that penetrate the SOI substrate 10 in a thickness direction are formed at positions overlapping the electrode pads PAD1 and PAD2, respectively. The through-electrode 14 is electrically connected to the electrode pad PAD1, whereas the through-electrode 15 is electrically connected to the electrode pad PAD2. The electrode pads PAD1 and PAD2 are thus extended to the outside via a lower surface of the MEMS device 1. This facilitates the electrical connection to an external apparatus, such as an oscillation circuit.

The resonator element 20 is provided with the vibrating substrate 21 formed on the surface silicon layer 13. That is, the vibrating substrate 21 is formed of a silicon substrate. Since the vibrating substrate 21 is formed of a silicon substrate, the vibrating substrate 21 can be formed by a silicon wafer process. Therefore, it is possible to easily process the vibrating substrate 21 and form the vibrating substrate 21 with high processing accuracy.

The vibrating substrate 21, which has a plate shape, has an upper surface and a lower surface, which are related to each other as a front surface and a back surface. As illustrated in FIG. 3, the vibrating substrate 21 includes a base 210 and three vibrating arms 22A, 22B, and 22C extending from the base 210. As illustrated in FIG. 4, the base 210 is supported by the silicon layer 11 and the BOX layer 12 positioned below, whereas the vibrating arms 22A, 22B, and 22C are separated from the BOX layer 12. Therefore, each of the vibrating arms 22A, 22B, and 22C is a cantilever beam, a base portion of which is cantilevered by the base 210. The entire vibrating substrate 21 is formed with the same thickness as the surface silicon layer 13.

As illustrated in FIG. 3, the vibrating arms 22A, 22B, and 22C extend from the base 210 toward the positive side in the Y-axis direction, which corresponds to the first direction, and are arranged side by side at equal intervals in the X-axis direction, which corresponds to the second direction. More specifically, the vibrating arm 22A is positioned at the center of the arrangement; the vibrating arm 22B is positioned on the positive side of the vibrating arm 22A in the X-axis direction; and the vibrating arm 22C is positioned on the negative side of the vibrating arm 22A in the X-axis direction. Each of the vibrating arms 22A, 22B, and 22C includes an arm 221 extending from the base 210 to the positive side in the Y-axis direction and a wide section 222 disposed on the tip end side of the arm 221. The wide section 222 is wider than the arm 221. Hereinafter, for convenience of the description, a length of the vibrating arms 22A, 22B, and 22C in the Y-axis direction is referred to as a “length”, and a length thereof in the X-axis direction is referred to as a “width”.

Each arm 221 is linear in shape and has a width constant in the Y-axis direction. The width of the wide sections 222 is larger than the width of the arms 221. Each wide section 222 is linear in shape and has a width constant in the Y-axis direction. With such a configuration, a mass of the tip end portion of each of the vibrating arms 22A, 22B, and 22C increases due to a mass effect of the wide section 222. Thus, if the resonance frequency of the resonator element 20 is the same, the whole length of each of the vibrating arms 22A, 22B, and 22C can be made shorter than that in a configuration in which the wide section 222 is not provided, thereby reducing the resonator element 20 in size. Alternatively, if the whole length of each of the vibrating arms 22A, 22B, and 22C is the same, the resonance frequency of the resonator element 20 can be made lower than that in the configuration in which the wide section 222 is not provided.

The resonator element 20 further includes a weight M in a film shape disposed on each of the upper surfaces of the wide sections 222 of the vibrating arms 22A, 22B, and 22C. By disposing the weights M, the masses of the wide sections 222 are increased, to make the mass effect described above more remarkable. A constituent material of the weights M is not particularly limited; however, this material preferably contains at least one of aluminum (Al), titanium (Ti), chromium (Cr), gold (Au), silver (Ag), copper (Cu), and polysilicon (Si). The term “aluminum (Al)” includes, in addition to aluminum, an aluminum compound, such as aluminum oxide or aluminum nitride. The same applies to the other materials described above. Although not illustrated, the weights M of the present embodiment have a configuration in which a surface layer of gold (Au) is stacked on a base layer of titanium (Ti). By using these materials, the weights M having a high specific gravity can be easily formed. However, the weights M may be omitted.

As illustrated in FIGS. 2 and 3, the resonator element 20 includes a temperature characteristic adjuster 24 that adjusts frequency-temperature characteristics of the resonance frequency. The temperature characteristic adjuster 24 includes a temperature characteristic adjustment film 24A disposed on an upper surface of the vibrating arm 22A, a temperature characteristic adjustment film 24B disposed on an upper surface of the vibrating arm 22B, and a temperature characteristic adjustment film 24C disposed on an upper surface of the vibrating arm 22C.

As illustrated in FIG. 4, each of the temperature characteristic adjustment films 24A, 24B, and 24C is disposed extend across the base 210 and the arm 221. In other words, each of the temperature characteristic adjustment films 24A, 24B, and 24C is disposed so as to overlap a boundary between the base 210 and the arm 221. The temperature characteristic adjustment films 24A, 24B, and 24C disposed in this manner are formed of a stacked body of a first layer 241, which is a silicon-oxide (SiO₂) layer, and a second layer 242, which is a zirconium-oxide (ZrO₂) layer. Furthermore, the stacked body is covered with a polysilicon layer 243, which is a covering layer. Silicon, which is a constituent material of the vibrating substrate 21, has frequency-temperature characteristics in which the resonance frequency decreases with an increase in the temperature. Silicon oxide (SiO₂) and zirconium oxide (ZrO₂) have, however, frequency-temperature characteristics in which the resonance frequency increases with an increase in the temperature. As a result, these frequency-temperature characteristics cancel each other, so that the frequency-temperature characteristics of the resonance frequency of the composite formed of the vibrating arms 22A, 22B, and 22C and the temperature characteristic adjustment films 24A, 24B, and 24C can be made closer to flat. By mounting the temperature characteristic adjusters 24, for example, the change amount ±3,000 ppm of the resonance frequency of the vibrating substrate 21 in the temperature range of −25° C. to +75° C. can be flattened to about ±200 ppm to ±500 ppm.

The configurations of the temperature characteristic adjustment films 24A, 24B, and 24C are not particularly limited. Each of the temperature characteristic adjustment films 24A, 24B, and 24C may be formed with one of the first layer 241 and the second layer 242. Moreover, each of the temperature characteristic adjustment films 24A, 24B, and 24C may include any other layer in addition to the first layer 241 and the second layer 242. Alternatively, the temperature characteristic adjusters 24 may be omitted.

As illustrated in FIG. 3, the resonator element 20 includes a driver 23 that subjects the vibrating arms 22A, 22B, and 22C to flexural deformation in the Z-axis direction. The driver 23 includes a piezoelectric element 23A disposed on the upper surface of the vibrating arm 22A so as to be stacked on the temperature characteristic adjustment film 24A, a piezoelectric element 23B disposed on the upper surface of the vibrating arm 22B so as to be stacked on the temperature characteristic adjustment film 24B, and a piezoelectric element 23C disposed on the upper surface of the vibrating arm 22C so as to be stacked on the temperature characteristic adjustment film 24C. The piezoelectric elements 23A, 23B, and 23C are shorter than the arms 221 and are disposed within substantially half areas of the vibrating arms 22A, 22B, and 22C on the base end side. In addition, the piezoelectric elements 23A, 23B, and 23C are shorter than a length L of each of the vibrating arms 22A, 22B, and 22C. In the present embodiment, the piezoelectric elements 23A, 23B, and 23C are disposed within substantially half areas of the vibrating arms 22A, 22B, and 22C on the base end side. In addition, the piezoelectric elements 23A, 23B, and 23C are disposed so as to extend across the base 210 and the respective arms 221. To balance the vibrations in the resonator element 20, at least the vibrating arms 22B and 22C positioned on both sides of the arrangement have the same configuration (shape and size); however, the vibrating arms 22A positioned at the center has a configuration (shape and size) different from that of the vibrating arms 22B and 22C as necessary. Details of this will be described later.

Each of the piezoelectric elements 23A, 23B, and 23C expands and contracts in the Y-axis direction in response to application of a drive voltage. By expanding and contracting the piezoelectric elements 23A, 23B, and 23C in the Y-axis direction, the vibrating arms 22A, 22B, and 22C are subjected to flexural vibration in the Z-axis direction.

The piezoelectric elements 23A, 23B, and 23C have the same configuration. As illustrated in FIG. 4, each of the piezoelectric elements 23A, 23B, and 23C includes a lower electrode 231, a piezoelectric layer 232 disposed on an upper surface of the lower electrode 231, and an upper electrode 233 disposed on an upper surface of the piezoelectric layer 232. Constituent materials of individual sections of the piezoelectric elements 23A, 23B, and 23C are not particularly limited. For example, the piezoelectric layer 232 is formed of aluminum nitride (AlN), and the lower electrodes 231 and the upper electrodes 233 are formed of titanium nitride (TiN). However, configurations of the piezoelectric elements 23A, 23B, and 23C are not particularly limited, and any other layers may be interposed between the respective layers.

As illustrated in FIG. 3, the piezoelectric elements 23A, 23B, and 23C disposed in the above manner are wired such that the vibrating arms 22A, 22B, and 22C arranged adjacent to each other are subjected to flexural vibration in mutually opposite phases. In other words, the piezoelectric elements 23A, 23B, and 23C are wired such that a first state in which the vibrating arms 22B and 22C are subjected to upward flexural vibration and the vibrating arm 22A is subjected to downward flexural vibration and a second state in which the vibrating arms 22B and 22C are subjected to downward flexural vibration and the vibrating arm 22A is subjected to upward flexural vibration are alternately repeated. More specifically, the lower electrodes 231 of the piezoelectric elements 23B and 23C and the upper electrode 233 of the piezoelectric element 23A are electrically connected to the electrode pad PAD1 via wires (not illustrated), whereas the upper electrodes 233 of the piezoelectric elements 23B and 23C and the lower electrode 231 of the piezoelectric element 23A are electrically connected to the electrode pad PAD2 via a wire (not illustrated).

By subjecting the vibrating arms 22A, 22B, and 22C adjacent to one another to flexural vibration in mutually opposite phases, as described above, the vibrations of the vibrating arms 22A, 22B, and 22C are at least partly canceled. It is thus possible to effectively suppress vibration leakage of the resonator element 20. The flexural vibrations of the vibrating arms 22A, 22B, and 22C are greatly excited at the resonance frequency, so that the impedance is minimized. As a result, connecting the MEMS device 1 to an oscillation circuit provides an oscillator that oscillates at a frequency determined by the resonance frequency.

The overall configuration of the resonator element 20 has been described above. Next, dimensions of the resonator element 20 will be described in detail. When, as illustrated in FIG. 3, of the three vibrating arms 22A, 22B, and 22C, the vibrating arm 22A positioned at a center of the arrangement is provided with the arm 221 having a width denoted by W1 and the vibrating arms 22B and 22C positioned on both sides of the arrangement are provided with the arms 221 having a width denoted by W2, the relationship 1≤W1/W2≤2 is satisfied. Regarding this relationship, the relationship 1.6≤W1/W2≤2.0 is satisfied, particularly in the present embodiment.

The reason for the above will be described below. In the resonator element 20, the vibrating arms 22A, 22B, and 22C are linearly deformed in response to forces applied by the expansion and contraction of the piezoelectric elements 23A, 23B, and 23C. In this case, as the expansion and contraction of the piezoelectric elements 23A, 23B, and 23C increase, amplitudes of the vibrating arms 22A, 22B, and 22C also increase. However, when forces of a certain level or more are applied to the vibrating arms 22A, 22B, and 22C, the spring rigidity of the vibrating arms 22A, 22B, and 22C apparently increases, and the vibrating arms 22A, 22B, and 22C are less likely to be further deformed. As a result, the linear relationship between the forces applied to the vibrating arms 22A, 22B, and 22C and the deformation of the vibrating arms 22A, 22B, and 22C is no longer satisfied. Such a phenomenon is referred to as nonlinearity of the spring. This nonlinearity may increase fluctuations of the vibration frequency of the resonator element 20 or may suddenly stop the oscillation of the resonator element 20, thereby affecting stability of the oscillation. Therefore, it is necessary to use the resonator element 20 within a range over which nonlinearity does not appear or is small.

Whereas the resonator element 20 has an issue of such nonlinearity, the vibrating arm 22A positioned at the center and the vibrating arms 22B and 22C positioned on both sides of the arrangement vibrate in opposite phases, as described above. When there is a difference between a total mass M1 (the mass of the vibrating arm 22B+the mass of the vibrating arm 22C) of the vibrating arms 22B and 22C vibrating in the same phase and a mass M2 of the vibrating arm 22A vibrating in the opposite phase, a lighter vibrating arm vibrates more greatly than a heavier one. As described above, when a part of the three vibrating arms 22A, 22B, and 22C vibrates more largely, the vibrating arm enters the nonlinear range earlier than the other vibrating arms, thus causing the nonlinearity described above to appear earlier. In this case, the nonlinearity appears at a lower driving voltage. Therefore, to make the nonlinearity less likely to appear, for example, the width W1 of the vibrating arm 22A may be made larger than the width W2 of the vibrating arms 22B and 22C. This can sufficiently decrease a difference between the total mass M1 and the mass M2, thereby making the amplitudes of the vibrating arms 22A, 22B, and 22C substantially equal to each other.

As illustrated in FIG. 5, however, as W1/W2, which expresses a ratio between the widths W1 and W2, increases, the Q value of the resonator element 20 decreases. That is, when W1/W2 is excessively increased for the purpose of making the nonlinearity less likely to appear, the Q value of the resonator element 20 decreases, also affecting the stability of the oscillation of the resonator element 20. In consideration of this, the resonator element 20 employs 1≤W1/W2≤2. Such a configuration can make the nonlinearity less likely to appear while keeping the Q value sufficiently high. Furthermore, setting 1.6≤W1/W2≤2.0 as in the present embodiment makes the nonlinearity further less likely to appear, thereby making the above-described effect more remarkable.

As illustrated in FIG. 6, as a ratio between a length Lh of the wide section 222 to a length L of the vibrating arms 22A, 22B, and 22C increases, the Q value of the resonator element 20 decreases. Therefore, to reliably set the Q value to 10,000 or more, which is an index of stable oscillation, the resonator element 20 employs Lh/L≤0.49 for each of the vibrating arms 22A, 22B, and 22C. Such a configuration can keep the Q value sufficiently high. Satisfying 1≤W1/W2≤2 and Lh/L≤0.49 as described above can make the nonlinearity less likely to appear while keeping the Q value sufficiently high. Therefore, it is possible to provide the resonator element 20 with high oscillation stability.

A lower limit of Lh/L is not particularly limited, however, preferably 0.2≤Lh/L. With this, the wide section 222 is not excessively reduced in size, thereby sufficiently exhibiting the mass effect of the wide section 222 described above. It is consequently possible to reduce the resonator element 20 in size.

The MEMS device 1 has been described above. The MEMS device 1 described above is provided with a resonator element 20, which includes a base 210 and three vibrating arms 22A, 22B, and 22C that extend from the base 210 in the Y-axis direction, which corresponds to the first direction, and that are arranged side by side in the X-axis direction, which corresponds to the second direction, the X-axis direction being orthogonal to the Y-axis direction. Each of the three vibrating arms 22A, 22B, and 22C includes an arm 221 extending from the base 210 and a wide section 222 positioned on a tip end portion of the arm 221, the wide section 222 being wider than the arm 221. When, of the three vibrating arms 22A, 22B, and 22C, the vibrating arm 22A positioned at a center of an arrangement is provided with the arm 221 having a width denoted by W1 which is a length in the X-axis direction, and the vibrating arms 22B and 22C positioned at both sides of the arrangement are provided with the arms 221 each having a width denoted by W2 which is a length in the X-axis direction, a relationship 1≤W1/W2≤2 is satisfied. When a length of the three vibrating arms 22A, 22B, and 22C in the Y-axis direction is denoted by L and a length of the wide sections 222 in the Y-axis direction is denoted by Lh, a relationship of Lh/L≤0.49 is satisfied. Such a configuration can make the nonlinearity less likely to appear while keeping the Q value sufficiently high. Therefore, it is possible to provide the resonator element 20 with high oscillation stability.

As described above, the resonator element 20 satisfies 0.2≤Lh/L. Such a configuration can reduce the resonator element 20 in size.

As described above, the resonator element 20 includes weights M having a film shape disposed on the respective wide sections 222. Such a configuration can make the wide sections 222 heavier, thereby making the mass effect of the wide sections 222 more remarkable.

As described above, a constituent material of the weights M contains at least one of aluminum, titanium, chromium, gold, silver, copper, and polysilicon. Such a configuration enables the weights M having a high specific gravity to be easily formed. This makes the mass effect of the wide sections 222 even more remarkable.

As described above, the resonator element 20 includes a driver 23 mounted on each of the arms 221. The driver 23 subjects each of the vibrating arms 22A, 22B, and 22C to flexural vibration in the Z-axis direction, which corresponds to a third direction, the Z-axis direction being orthogonal to both the Y-axis direction and the X-axis direction. Such a configuration can subject the vibrating arms 22A, 22B, and 22C to flexural vibration efficiently.

As described above, the driver 23 is mounted so as to extend across each arm 221 and the base 210. Such a configuration can subject the vibrating arms 22A, 22B, and 22C to flexural vibration further efficiently.

As described above, the resonator element 20 includes a temperature characteristic adjuster 24 which is mounted in each arm 221 and adjusts frequency-temperature characteristics. Such a configuration can improve the frequency-temperature characteristics of the vibrating substrate 21.

Hereinabove, the resonator element according to an embodiment of the present disclosure has been described with reference to the accompanying drawings; however, the present disclosure is not limited to such embodiments. A configuration of each section can be replaced with another configuration having a substantially equivalent function. Furthermore, any other components may be added to the present disclosure. For example, the vibrating substrate 21 is made of silicon in the foregoing embodiment; however, the present disclosure is not limited thereto. For example, the vibrating substrate 21 may be made of quartz crystal or may be made of a piezoelectric material other than quartz crystal. In this case, the driver can be formed of electrodes disposed on the vibrating substrate 21.

What is claimed is:

1. A resonator element comprising:
a base; and
three vibrating arms that extend from the base in a first direction and that are arranged side by side in a second direction orthogonal to the first direction,
each of the three vibrating arms including an arm extending from the base and a wide section positioned at a tip end portion of the arm, the wide section being wider than the arm, wherein
when, of the three vibrating arms, the vibrating arm positioned at a center of an arrangement is provided with the arm having a width denoted by W1 which is defined as a length of the arm in the second direction, and the vibration arms positioned on both sides of the arrangement are provided with the arms each having a width denoted by W2 which is defined as a length of the arms in the second direction, a relationship 1≤W1/W2≤2 is satisfied, and
when a length of the three vibrating arms in the first direction is denoted by L and a length of the wide sections in the first direction is denoted by Lh, a relationship of Lh/L≤0.49 is satisfied.

2. The resonator element according to claim 1, wherein a relationship 0.2≤Lh/L is satisfied.

3. The resonator element according to claim 1, further comprising a weight disposed on each of the wide sections, the weight having a film shape.

4. The resonator element according to claim 3, wherein a constituent material of the weight contains at least one of aluminum, titanium, chromium, gold, silver, copper, and polysilicon.

5. The resonator element according to claim 1, further comprising a driver that subjects each of the vibrating arms to flexural deformation in a third direction orthogonal to the first direction and the second direction, the driver being mounted in each of the arms.

6. The resonator element according to claim 5, wherein the driver is mounted to extend across the base and each of the arms.

7. The resonator element according to claim 1, further comprising a temperature characteristic adjuster that adjusts a frequency-temperature characteristic, the temperature characteristic adjuster being mounted in each of the arms.
